(19) United States
(12) Patent Application Publication
(10) Pub. No.: US 2006/0250078 A1
(43) Pub. Date: Nov. 9, 2006

(54) Organic electroluminescent devices incorporating UV-illuminated fluorocarbon layers

(75) Inventors: Chun Sing Lee, Hong Kong (CN); Shuit-Tong Lee, Hong Kong (CN); Shi Wun Tong, Hong Kong (CN); Yeshayahu Lifshitz, Haifa (IL)

Correspondence Address: HESLIN ROTHENBERG FARLEY & MESITI PC, 5 COLUMBIA CIRCLE, ALBANY, NY, 12203, US

(73) Assignee: CITY UNIVERSITY OF HONG KONG, Hong Kong (CN)

(21) Appl. No.: 11/124,686

(22) Filed: May 9, 2005

(51) Int. Cl. H05B 33/00

(52) U.S. Cl. 313/506; 313/504

(57) ABSTRACT

A simple and efficient method of increasing conductivity of the fluorocarbon film is disclosed. By illuminating the fluorocarbon film under ultraviolet light (UV-CFx), the film conductivity can be increased by five orders of magnitude. Devices using such a UV-treated, conductive fluorocarbon film as a buffer layer give much better performance in terms of lower operational voltage and enhanced operational stability. The improved smoothness and lowered hole injection barrier height with UV-CFx are responsible for the enhanced performance of electroluminescent devices.

### FIELD OF THE INVENTION

This invention relates to a method for improving the properties of fluorocarbon films in organic electroluminescent devices or organic light-emitting diodes (OLEDs) and to such devices obtained thereby. In particular ultraviolet light-illuminated fluorocarbon films achieve significant improvement in conductivity, smoothness, and hole injection behavior. Such a modified fluorocarbon film is particularly effective in decreasing the operational voltage and improving the stability of OLEDs.

### BACKGROUND OF THE INVENTION

OLEDs for flat panel displays are currently receiving a great deal of attention. Although the performance of many OLEDs is already marketable, performance enhancements in operation stability and driving voltage remain highly desirable. Indium tin oxide (ITO) is the most commonly used anode in OLEDs, and intensive effort has been expended on improving the morphology and hole injection behavior of ITO. Various hole-injecting buffer layers including Hf-doped ITO layer as reported by T.-H. Chen, Applied Physics Letters, v. 85, 2092 (2004), silver oxide (Ag.sub.2O) as reported by Xiao Buwen, Microelectronics Journal, v. 36, 105 (2005), and ultrathin tris-(8-hydroxyquinoline) aluminum (Alq) as described by Yoon-Fei Liew, Applied Physics Letters, v. 85, 4511 (2004) have been reported to improve the hole injection at the ITO/organic interface.

Plasma-polymerized fluorocarbon films are also the promising materials as the good buffer layer. Such films could improve the interface morphology between ITO and organic materials and could also efficiently impede indium diffusion from ITO and hence reduce the device degradation process. However, the films prepared by plasma polymerization are generally insulating and lead to a large voltage drop throughout the OLEDs. The low reproducibility of forming conductive fluorocarbon films is also highly undesirable. Hence there is a need for developing a simple and reliable process for preparing fluorocarbon films with high conductivity.

### SUMMARY OF THE INVENTION

According to the present invention there is provided an organic electroluminescent device comprising:
a) a substrate formed of an electrically insulating material;
b) a hole-injecting anode layer mounted on the substrate;
c) a fluorocarbon film treated by illumination with ultra-violet light;
d) an organic light-emitting structure formed over the fluorocarbon film;
e) an electron-injecting cathode formed by co-evaporating two conductive metals.

The insulating substrate may be either optically transparent (e.g. formed from glass or plastics materials) or opaque (e.g. formed from a ceramic or semi-conducting material). The anode may be optically transparent with a work function larger than 4 eV. For example, the anode material may be chosen from the group consisting of metal oxides, titanium nitride, semi-transparent gold or a conducting polymer. The metal oxides may include indium tin oxide, fluorine-doped tin oxide, indium-doped zinc oxide, nickel-tungsten oxide and cadmium-tin oxide. Possible materials for the conducting polymer include poly(3,4-ethylenedioxythiophene) poly(styrenesulfonate) (PEDOT:PSS) and PSS-doped polyaniline.

The fluorocarbon film may be either insulating or conducting.

In some embodiments, the organic light-emitting structure comprises:
(i) an organic hole-transporting layer formed on the fluorocarbon film; and
(ii) an organic electroluminescent layer formed on the hole-transporting layer.

Possible materials for the organic hole-transporting layer include aromatic tertiary amines, possible materials for the organic electroluminescent layer include materials selected from the group consisting of metal chelated oxinoid compounds, 9,10-di-(2-naphthyl) anthracene (DNA), poly(9,9-dioctylfluorene) (PFO) and PFO copolymers.

Preferably the cathode is formed of a material having a work function no larger than 4 eV.

Preferably the surface of the fluorocarbon layer has a surface roughness of less than 1.6 nm.

Preferably the fluorocarbon layer has a resistivity of the order of 10⁵ Ω-cm.

Preferably the fluorocarbon layer has a resistivity of less than 10⁶ Ω-cm.

According to another aspect of the invention there is provided a method of forming an electroluminescent device comprising:
a) depositing an anode layer on a substrate,
b) depositing a fluorocarbon layer on the anode layer,
c) exposing the fluorocarbon layer to ultra-violet light,
d) forming an organic light-emitting structure over the fluorocarbon layer, and
e) forming an electron-injecting cathode over the organic light-emitting structure.

In an embodiment of the invention the ultra-violet light is supplied by a UV mercury lamp with an intensity of 14 mW/cm². The fluorocarbon layer is preferably exposed to ultra-violet light for about 30 seconds with a total dosage of at least 420 mJ/cm².

### BRIEF DESCRIPTION OF THE DRAWINGS

Some embodiments of the present invention will now be described by way of example and with reference to the accompanying drawings, in which:

FIG. 1 is a schematic diagram of an example of a conventional OLED in which a light-emitting structure is deposited on an ITO anode,

FIG. 2 is a schematic diagram of an OLED in which a fluorocarbon film or ultraviolet-light illuminated fluorocarbon film is interposed between a light-emitting structure and an ITO anode,

FIG. 3A is a graph that shows the current density as a function of the bias voltage for an example of the invention and the prior art,

FIG. 3B is a graph that shows the luminance as a function of the bias voltage for an example of the invention and the prior art,

FIG. 3C is a graph that shows the current density and luminance as a function of the bias voltage for an example of the invention and the prior art,

FIG. 4 is a graph that shows the current efficiency as a function of the current density for an example of the invention and the prior art,

FIG. 5 is a graph that shows the normalized luminance (to the beginning value) as a function of the operation time for an example of the invention and the prior art,

FIG. 6 is a graph that shows the results of the XPS C 1s core level spectra, which are obtained from the structure of (a) fluorocarbon film/ITO and (b) ultraviolet-light illuminated fluorocarbon film/ITO,

FIG. 7A is a schematic showing the relative energy levels at the interfaces between hole-transporting layer and different layered structures: ITO, fluorocarbon film/ITO, and ultraviolet-light illuminated fluorocarbon film/ITO,

FIG. 7B is the same as FIG. 7A but the energy levels were measured after 5 days air exposure of the samples,

FIG. 8 shows the atomic force microscopy (AFM) 3-dimensional (3-D) images of (a) ITO, (b) fluorocarbon film/ITO, and (c) ultraviolet-light illuminated fluorocarbon film/ITO,

FIG. 9 shows the AFM line scanning profile of ITO, fluorocarbon film/ITO, and ultraviolet-light illuminated fluorocarbon film/ITO,

FIG. 10 is the AFM 3-D images of hole-transporting layer deposited on the layered structures described in FIG. 8,

FIG. 11 is the AFM line scanning profile of hole-transporting layer deposited on the layered structure described in FIG. 9,

FIG. 12 is the same as FIG. 8 but the AFM images were measured after 5 days air exposure of the samples,

FIG. 13 is same as FIG. 9 but the AFM line profiles were measured after 5 days air exposure of the samples,

FIG. 14 shows the spectrum of a UV mercury lamp which may be used in embodiments of the invention, and

FIGS. 15(a) and (b) show (a) current density and (b) luminance characteristics as a function of voltage for OLEDs with different anodes: uncoated ITO glass, ITO glass coated with pristine CFₓ or UV-CFₓ for different UV illumination times.

### DETAILED DESCRIPTION OF THE PREFERRED EMBODIMENTS

As will be seen from the following description, at least in preferred embodiments the present invention provides for significantly improved properties, such as increased conductivity, of fluorocarbon films used OLEDs and other electroluminescent devices.

In particular the fluorocarbon films (UV-CFx) are illuminated with ultraviolet light in the wavelength of 270 nm to 350 nm. By this means the otherwise high resistivity of the fluorocarbon films (e.g. 10¹⁰ ohm-cm) can be significantly decreased to the desired value of 10⁵ ohm-cm (i.e., a reduction of five orders of magnitude). Remarkable improvements in the device performance (e.g. current density—voltage—luminance characteristics) for the UV-CFx coated anode can be achieved. For example, in OLEDs with exposure to air the performance of an UV-CFx coated anode is only slightly worsened, whereas there would otherwise be significant degradation. The operational stability of the OLEDs can thus be remarkably improved.

Another advantage of the present invention, at least in preferred embodiments, is that holes can be injected from anode to hole-transporting layer more efficiently. A UV-CFx coated anode has significant benefits in terms of its lower hole injection barrier height at the interface between the anode and hole-transporting layer.

A UV-CFx-coated anode also exhibits pronounced improvement in its morphology. Growth of hole-transporting layer on the UV-CFx coated anode follows the smooth topography well.

A method and system for preparing fluorocarbon films in accordance with embodiments of the invention is described as follows:

A plasma deposition system is connected to a rotary pump with a base pressure of 10⁻⁴ Torr. During this deposition, the chamber was continuously pumped while trifluoromethane (CHF₃) gas was fed into the chamber to maintain a pressure of 500 mTorr. A power of 20 Watts and a frequency of 40 kHz or 13.56 MHz are selected to generate the plasma between two 7.5 cm-diameter electrodes. After the fluorocarbon film is deposited on the substrate, it is immediately transferred to another deposition system.

A system and method to perform the ultraviolet-light (UV) illumination is described as follows:

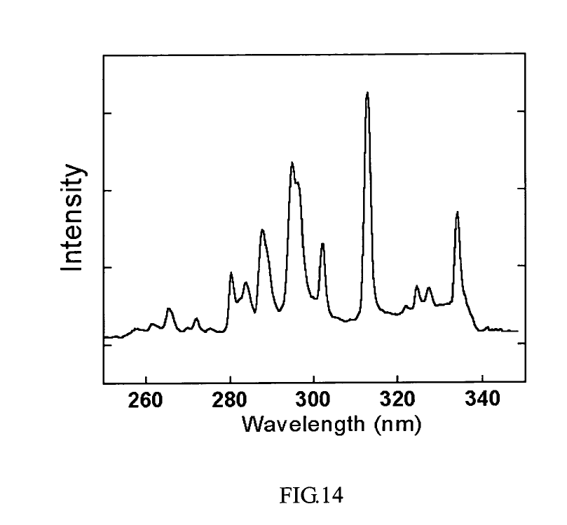

UV illumination (λ˜270-350 nm) of the fluorocarbon film is performed with a mercury lamp in a dry box filled with pure nitrogen (oxygen and moisture levels were less than 1 ppm). The nitrogen gas protects the fluorocarbon film and the substrate from the atmospheric oxygen and water. The fluorocarbon film is then exposed to the UV irradiation for 30 seconds with a total dosage of 420 mJ/cm². FIG. 14 shows the typical spectrum of a UV mercury lamp that may be used in embodiments of the invention.

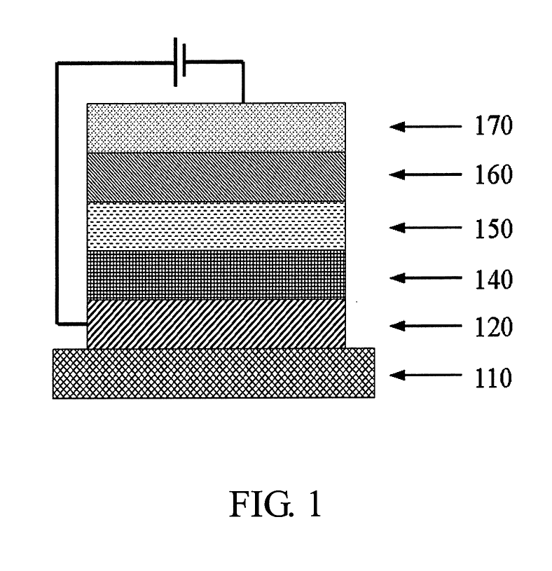

Referring to FIG. 1, a conventional OLED 100 is composed of several layers. A conductive anode contact 120 is formed on an insulating substrate 110. An organic light-emitting structure 180 is thermally evaporated from tantalum boats onto the anode contact 120. The organic light-emitting structure 180 consists of the hole-transporting layer 140, light-emitting layer 150, and electron-transporting layer 160. They are deposited on the anode contact 120 in sequence. A cathode contact 170 is finally deposited on the organic light-emitting structure 180.

The detailed description of every layer in the device 100 is shown as below:

The insulating substrate 110 may be either optically transparent or opaque depending on the intended application of the device. Glass or plastics materials for example may be chosen to form a transparent substrate, while if the substrate is to be opaque then possible materials are ceramics or semi-conducting materials.

The conductive anode 120 is optically transparent with a work function larger than 4 eV. In the embodiments of the present invention to be discussed below, the anode 120 is formed of a conductive and transparent metal oxide. Possible such metal oxide groups include indium tin oxide, fluorine-doped tin oxide, indium-doped zinc oxide, nickel-tungsten oxide and cadmium-tin oxide. Indium tin oxide (ITO) is particularly preferred as the anode material because of its high transparency, good conductivity, and high work function.

The organic hole-transporting layer in embodiments of the present invention comprises tertiary amines. They can be used as the host material in a doped hole-transport layer or a doped sublayer of a hole-transport layer. They can also be used as the sole material of an undoped hole-transport layer or an undoped sublayer of a hole-transport layer. Particularly preferred is α-naphtylphenyliphenyl diamine (NPB) as used by T. H. Chen et al. in Applied Physics Letters, v. 85, 2092 (2004).

The light-emitting layer 150 is selected from the group of metal chelated oxinoid compounds, 9,10-di-(2-naphthyl) anthracene (DNA), poly(9,9-dioctylfluorene) (PFO) and PFO copolymers. This layer should be chosen to have a high luminescent efficiency, and a well known material for this purpose is Alq, which produces excellent green electroluminescence.

The electron-transporting layer 160 facilitates the movement of electrons from cathode contact 170 to light-emitting layer 150. Preferred material for use in forming this layer include, e.g., Alq, 5-bis(10-hydroxy-benzo(h)quinolinato) beryllium and bis(2-(2-hydroxy-phenyl)-benzolthiazolato) zinc. Alq is used in preferred embodiments of the present invention.

The conductive cathode contact 170 has the work function not larger than 4 eV. The cathode contact 170 can be made either transparent or opaque. Co-evaporated Mg:Ag metal layer is commonly used for a cathode that can enhance electron injection in the device. In embodiments of the present invention, this opaque Mg:Ag metal is selected as the cathode contact in device 100. Measurement of light emission is obtained from the transparent anode contact 120.

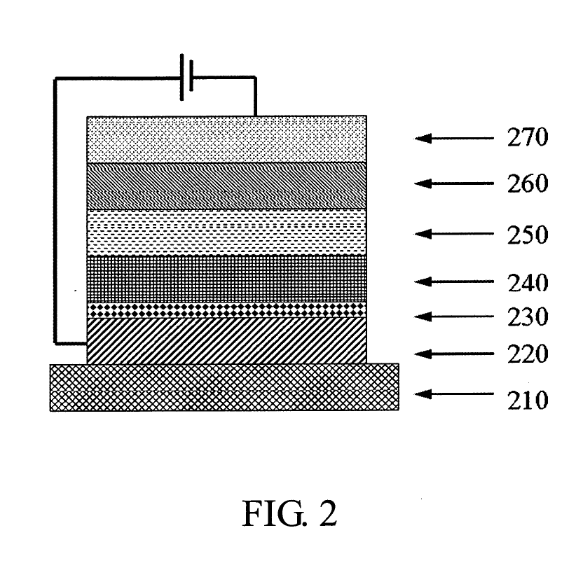

Regarding FIG. 2, the pristine fluorocarbon film (CFx) or ultraviolet light-illuminated fluorocarbon film (UV-CFx) 230 is interposed between the anode contact 220 and light-emitting structure 280. The organic electroluminescent device 200 consists of the substrate 210, anode contact 220, CFx or UV-CFx 230, light-emitting structure 280 and cathode contact 270. The function, materials and structure of the layers 210, 220, 240 to 280 are the same as the respective layers 110, 120, 140 to 180 shown in FIG. 1. The same thickness of the CFx layer and the UV-CFx layer provides a clear picture of the device improvement.

Device degradation is strongly related to the stability of the anode surface. To show the stability improvement that may be obtained using embodiments of the present invention, at least three sets of organic electroluminescent devices 100 and 200 were fabricated. The purpose of every set of devices is described below,

Set A: Measurement of current density-voltage-luminance (J-V-L) characteristics. The J-V-L characteristics of the non-encapsulated device 100 and 200 were measured simultaneously with a programmable Keithley model 237 power source and a Photoresearch PR 650 spectrometer.

Set B: Measurement of short-term operational stability.

Prior to the deposition of the light-emitting structure 180 and 280, the anode contact 120, CFx-coated anode and UV-CFx-coated anode 220 were exposed to air for five days with a relative humidity of 60%. The stabilization effect with the fluorocarbon film was compared by measuring the J-V-L characteristics of the devices. The J-V-L characteristics were measured simultaneously with a programmable Keithley model 237 power source and a Photoresearch PR 650 spectrometer.

Set C: Measurement of long-term operational stability.

The devices 100 and 200 were encapsulated in a dry box. The operational stability of the encapsulated electroluminescent devices in ambient environments was determined by measuring the changes in the luminance as a function of time when they were operated at a constant current density of 20 mA/cm².

Resistivities of the CFx layer were determined from I-V measurement through two silver electrodes deposited on CFx coated on insulating glasses. X-ray Photoelectron Spectroscopy (XPS) and Ultraviolet-light Photoelectron Spectroscopy (UPS) were used to analyze the changes in the chemical bonding and the injection barrier height with the films respectively. The analysis was done by transferring the films to the chamber of a VG ESCALAB 220i-XL photoelectron spectroscopy system. The base pressure of the analysis chamber is better than 10⁻¹⁰ mbar. Contact angle measurement is a straightforward method to show the wetability of the films. This measurement was performed using a digital camera to record the image of a deionized water drop on the film surface. The intercept of the semi-ellipse representing the drop with a reference line positioned at the film and drop interface was determined as the corresponding contact angle. Atomic Force Microscopy (AFM) measurements were carried out with a Nanoscope III A (Digital Instruments) scanning probe microscope with an etched silicon probe. The roughness of the films was measured by tapping mode AFM operated in air.

### EXAMPLES

The invention and its advantages are further illustrated by the specific examples that follow.

For the brevity of description, the materials and the layers formed will be abbreviated as shown below:
ITO: indium-tin oxide (anode contact)
CFx: fluorocarbon film prepared from plasma polymerization of a CHF₃ gas
UV-CFx: Ultraviolet light-illuminated fluorocarbon film prepared from plasma polymerization of a CHF₃ gas
NPB: α-napthylphenylbiphenyl diamine (hole-transporting layer)
Alq: tris-(8-hydroxyquinoline) aluminum (combined electron-transporting layer and light-emitting layer)
Mg:Ag: magnesium:silver co-evaporated in a volume ratio of 10:1 (cathode contact)

### Example 1

An electroluminescent device was constructed following the conventional structure as shown in FIG. 1:
a) a transparent anode contact, glass coated with ITO, was sequentially ultrasonicated in a commercial detergent, rinsed in deionized water, and then baked in an oven at 120° C. for about one hour. The substrates were further treated with UV-ozone treatment for 25 minutes;
b) the substrate was transferred to a vacuum deposition chamber at once;
c) a 60 nm NPB hole-transporting layer was deposited on ITO substrate by thermal evaporation;
d) a 60 nm Alq electron-transporting and light-emitting layer was deposited on the NPB layer by thermal evaporation;
e) a 200 nm co-evaporated Mg:Ag cathode contact was deposited on the Alq layer by thermal evaporation. All organic layers were deposited under the pressure of 10⁻⁶ mbar.

### Example 2

An electroluminescent device was constructed following the structure as shown in FIG. 2:
a) a transparent anode contact, glass coated with ITO, was sequentially ultrasonicated in a commercial detergent, rinsed in deionized water, and then baked in an oven at 120° C. for about one hour. The substrate was further treated with UV-ozone treatment for 25 minutes;
b) the substrate was then loaded into a vacuum chamber using a 40 kHz power generator in a parallel plate reactor;
c) a 2 nm CFx layer was deposited on the ITO anode by plasma polymerization of CHF₃ with a power of 20 Watts;
d) a 60 nm NPB hole-transporting layer was deposited on the CFx layer by thermal evaporation;
e) a 60 nm Alq electron-transporting and light-emitting layer was deposited on the NPB layer by thermal evaporation;
f) a 200 nm co-evaporated Mg:Ag cathode contact was deposited on the Alq layer by thermal evaporation. All organic layers were deposited under a pressure of 10⁻⁶ mbar.

### Example 3

An electroluminescent device was prepared following the same sequence as described in Example 2, except that the CFx layer was replaced by an UV-CFx layer of the same thickness. In this example the high resistivity of the as-deposited CFx layer was reduced to 10⁵ ohm-cm by illumination with the UV light at a wavelength of 270-350 nm for 30 seconds at the dosage of 420 mJ/cm².

In order to investigate the performance of the UV-CFx layer in organic electroluminescent devices, a drive voltage was applied to the devices of Examples 1 to 3.

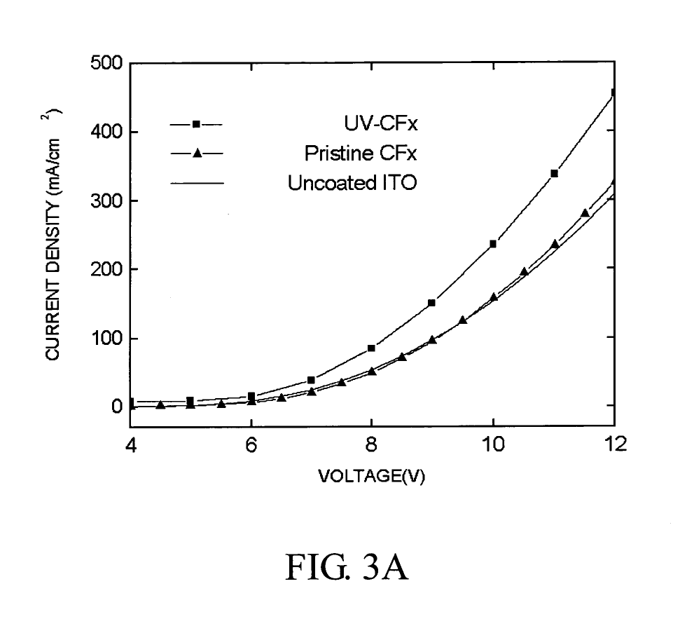

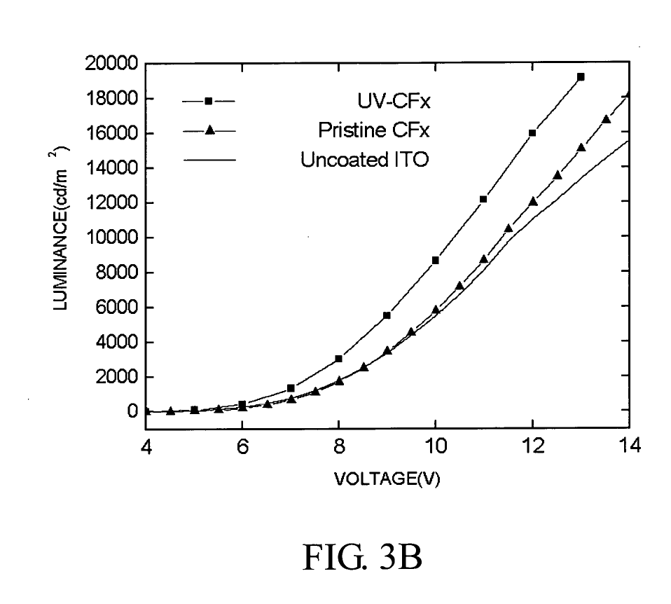

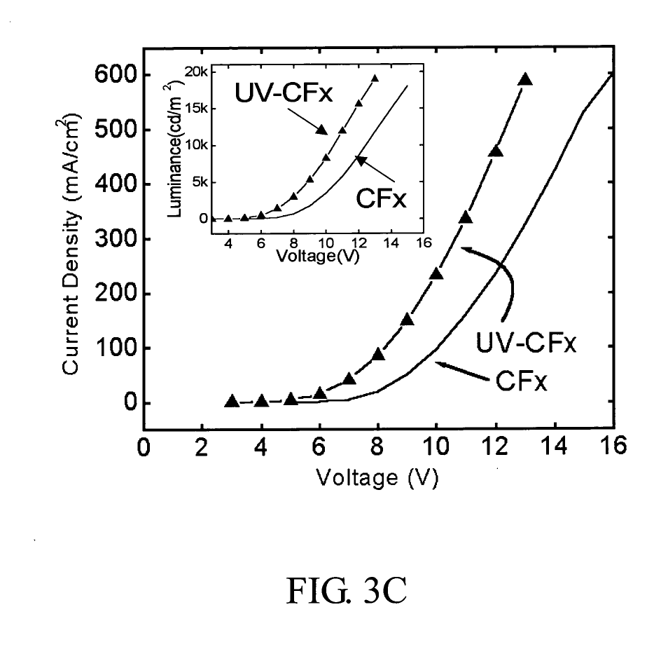

FIG. 3A and FIG. 3B show the current density and the luminance as a function of bias voltage of Example 1 to 3. Both J-V and L-V curves shift to a lower driving voltage.

The current density at 10 V of the UV-CFx device is 1.5 times higher than that of the pristine CFx and uncoated ITO devices. This increased current density is most likely due to the improved hole-injection from the ITO anode to the less resistive CFx buffer layer. The UV-CFx device at 10 V exhibits the luminance of 8651 cd/m² compared to 5790 and 5505 cd/m² for the pristine CFx and the uncoated ITO devices respectively.

The conductive UV-CFx device may be advantageously used in electroluminescent devices because of its much lower operational voltage.

### Example 4

An electroluminescent device was prepared following the same method as described in Example 2, except that the substrate was plasma-treated with oxygen, rather than UV-ozone treatment. The 2 nm CFx layer was deposited by using a 13.56 MHz power generator, instead of 40 kHz's.

### Example 5

An electroluminescent device was prepared following the same sequence as described in Example 4, except that the CFx layer was replaced by an UV-CFx layer of the same thickness.

Only very low current (about 0.00003 mA) was attained in the resistivity measurement on MHz system prepared CFx even under a voltage of 30V (much higher than 10¹¹ ohm-cm). The high resistivity of the as-deposited CFx layer was reduced to 10⁶ ohm-cm by illumination with UV light at a wavelength of 270-350 nm.

FIG. 3C shows the current density as a function of bias voltage in Example 4 and 5. The inset in the figure depicts their relative luminance as a function of bias voltage. Both J-V and L-V curves shift to a lower driving voltage. With an operational voltage of 10V, the luminance of the UV-CFx device was 8250 cd/m² compared to 3462 cd/m² for the pristine CFx. Similarly, the voltage required to achieve a current density of 100 mA/cm² for the MHz prepared UV-CFx devices was reduced to 8.2V, while that for the pristine CFx devices was 10.1V. Reduced operational voltage of the UV-CFx devices should be ascribed to its more conductive behavior.

### Example 6

An electroluminescent device was prepared following the same method as described in Example 1, except that the UV-ozone treated ITO anode was exposed to air for five days before the deposition of organic layers.

### Example 7

An electroluminescent device was prepared following the same method as described in Example 2, except that the CFx-coated ITO anode was exposed to air for five days before the deposition of other organic layers.

### Example 8

An electroluminescent device was prepared following the same method as described in Example 3, except that the UV-CFx coated ITO anode was exposed to air for five days before the deposition of other organic layers.

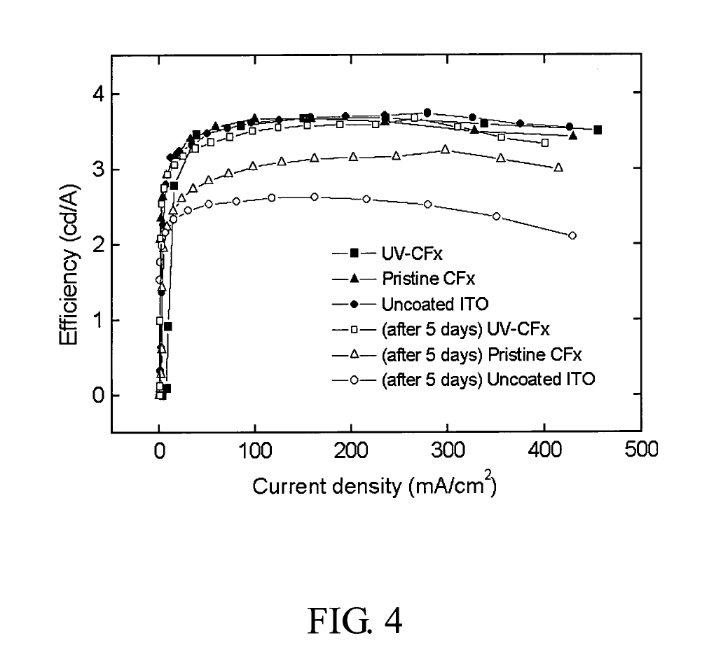

FIG. 4 shows the current efficiency as a function of current density of Example 1 to 3 and 6 to 8. Apparently, there is little impact on the performance of the UV-CFx device (example 8) even though the UV-CFx layer was exposed to air for five days. The current efficiency of the device fabricated on a bare ITO anode (example 6) drastically decreased from 3.6 cd/A to 2.6 cd/A. In contrast, the efficiency of the device with the UV-CFx coated ITO anode (example 8) is almost the same even after five days air exposure. The performance of the pristine CFx-coated anode (example 7) was degraded, though not to the same extent as the bare ITO anode. The result confirms that the UV-CFx layer does provide a more stable ITO surface against air exposure. The device performance was not adversely affected, even though the light-emitting structure and cathode were not deposited on the anode at once.

### Example 9

An electroluminescent device was prepared following the same method as described in Example 1, except that the thickness of NPB layer and Alq layer was replaced by 72 nm and 48 nm respectively. The device was encapsulated and was driven at a constant current density of 20 mA/cm².

### Example 10

An electroluminescent device was prepared following the same method as described in Example 2, except that the thickness of NPB layer and Alq layer was replaced by 72 nm and 48 nm respectively. The device was encapsulated and was driven at a constant current density of 20 mA/cm².

### Example 11

An electroluminescent device was prepared following the same method as described in Example 3, except that the thickness of NPB layer and Alq layer was replaced by 72 nm and 48 nm respectively. The device was encapsulated and was driven at a constant current density of 20 mA/cm².

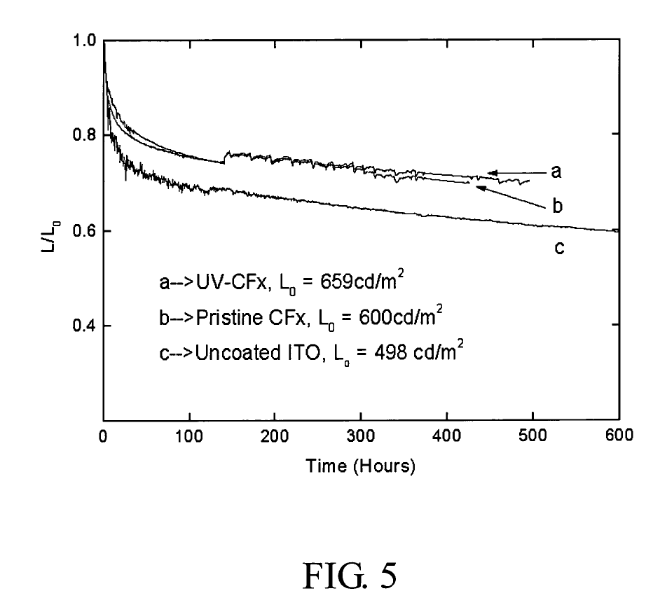

FIG. 5 shows the operational stability of the devices of Examples 9 to 11. The initial luminance of the device fabricated with the UV-CFx layer was 659 cd/m² while that with CFx layer and uncoated ITO was 600 cd/m² and 498 cd/m² respectively. The luminance of the device with bare ITO substrate lost about 30% after 64 hours of operation while that with UV-CFx layer maintained 70% of the initial luminance for more than 480 hours of operation. The result indicates that the UV-CFx layer on ITO significantly improves the operational stability of the device.

### Example 12

The following tests were conducted to study both chemical and physical improvement of the fluorocarbon films used in embodiments of the present invention. In all tests, an ITO-coated glass was chosen as the substrate. Chemical bonding modification, hydrophobic property, morphology and hole injection barrier height measurements were conducted.

The tests conducted were as follow:

1. X-Ray Photoelectron Spectroscopy (XPS) Measurement

As can be seen from the above, using certain embodiments of the present invention, the resistivity of the CFx layer can be substantially reduced from 10¹⁰ ohm-cm to 10⁵ ohm-cm. This change can be explained by the chemical bonding changes in the film.

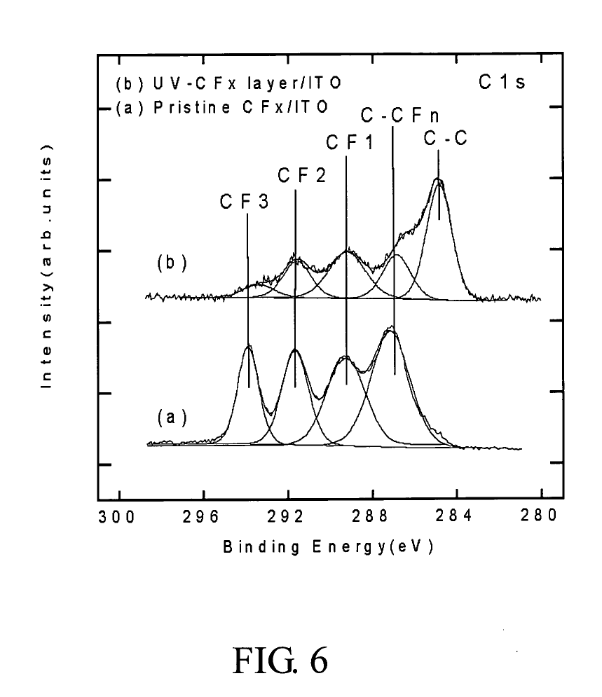

FIG. 6 shows the XPS C Is core level spectra of the CFx and the UV-CFx layers. Using the F is core level (688 eV) as an internal reference, the C is spectrum composes of four peaks (287.4, 289.6, 291.8 and 294.0 eV) assigned in an increasing energy to C—CFₙ, CF₁, CF₂ and CF₃. Curve a shows the CFx layer has a branched structure with many CFₙ groups originating from the CHF₃ in the non-biased plasma used for the deposition. No C—C peak at 284.8 eV can be observed.

Curve b clearly shows the appearance of a new peak at 284.8 eV, which is attributed to the C—C bond. The near-UV energy of 270-350 nm (˜3.6-4.6 eV) is insufficient to break the C—F bonding (bond energy 5.1 eV) but part of it is sufficient to break C—H bonds (bond energy 4.3 eV). This leads to a reduction of the CFₙ fraction and the increase of the C—CFₙ fraction. C—C clusters also form due to the initial non-homogeneous distribution of the C atoms in the CFx film, which is not affected by the UV (UV does not displace atoms). These clusters are responsible for the increase of the conductivity of the UV-CFx layer

2. Contact Angle Measurement

The contact angle of the deionized water drop to the surface of ITO, CFx layer and UV-CFx layer were measured to be 10°, 29° and 42° correspondingly. The best improvement in hydrophobicity was obtained for UV-CFx layer. This result explains why the UV-CFx layer can protect the ITO anode during the air exposure. The performance of the device with air-exposed UV-CFx layer was only negligibly affected comparing to that with uncoated ITO anode.

3. Ultraviolet Photoelectron Spectroscopy (UPS) Measurement

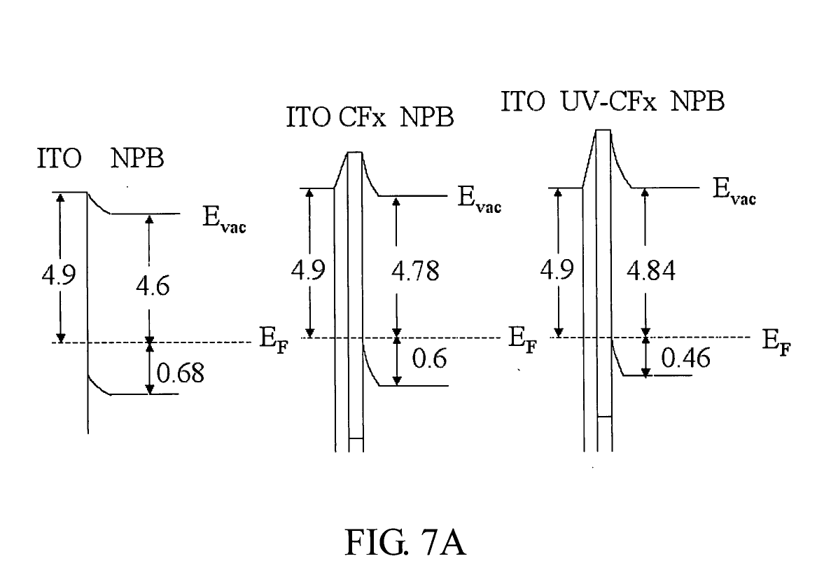

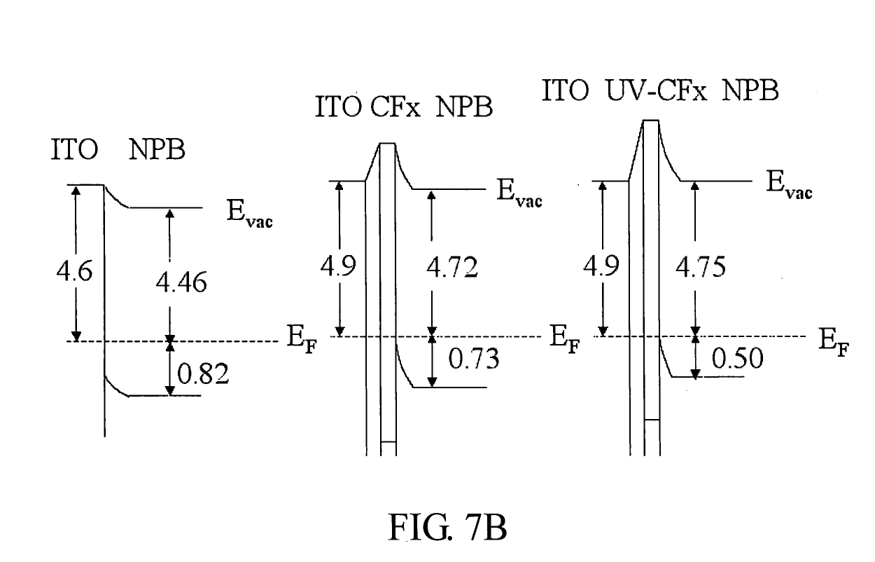

FIGS. 7A and 7B show the hole-injection barriers from ITO to NPB without and with air exposure respectively. Three types of samples: Bare ITO substrate, 2 nm thick CFx-coated ITO and 2 nm thick UV-CFx-coated ITO were prepared. Further, a 2 nm NPB layer was deposited on each of these samples for UPS measurement.

From FIG. 7A, the hole-injection barriers from ITO to NPB in the ITO/NPB, ITO/CFx layer/NPB, and ITO/UV-CFx layer/NPB system were found to be 0.68, 0.6 and 0.46 eV respectively. The changes in the hole-injection barriers are consistent with the I-V characteristics observed in the devices. The small reduction in hole-injection barrier (from 0.68 to 0.6 eV) due to the CFx layer causes the slightly increased current density in the device compared with bare ITO anode. The hole-injection barrier (from 0.68 to 0.46 eV) is more significantly reduced by the UV-CFx layer, which leads to a much larger current increase.

FIG. 7B shows the effect of the air exposure on the hole-injection barriers from ITO to NPB. Three types of samples: Bare ITO substrate, 2 nm thick CFx-coated ITO and 2 nm thick UV-CFx-coated ITO were prepared. Then they were exposed to air for five days under the humidity of 60%. Further, a 2 nm NPB layer was deposited on each these samples for UPS measurement.

By comparing FIGS. 7A and 7B, the increase of hole-injection barrier from ITO to NPB in the ITO/UV-CFx layer/NPB system is only 0.04 eV after five days air exposure (from 0.46 to 0.50 eV). However, the barrier height for ITO/NPB and ITO/CFx layer/NPB are more significantly increased from 0.68 and 0.6 eV to 0.82 and 0.73 eV respectively. The increase in barrier height is in good agreement with the electroluminescent characteristics. Air-exposed UV-CFx device had negligible increase in injection barrier that lead to the unchanged current efficiency compared with that without air exposure.

4. Atomic Force Microscopy (AFM) Measurement

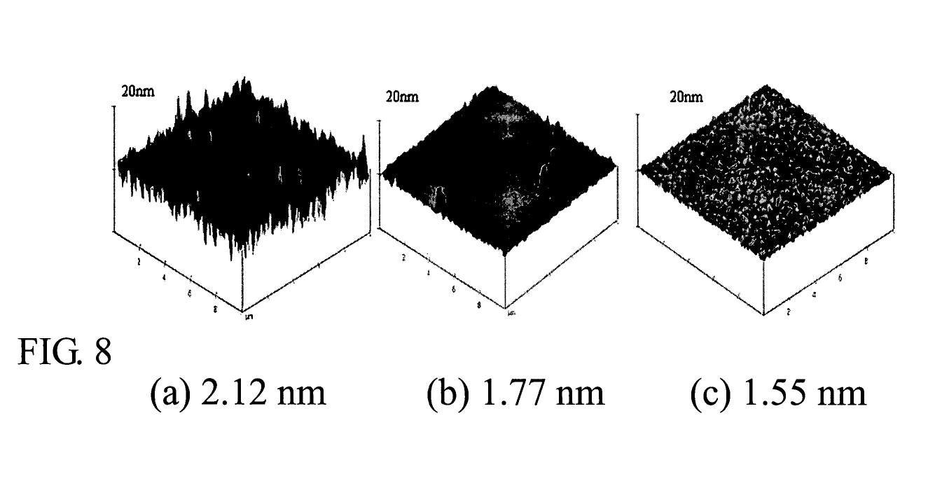

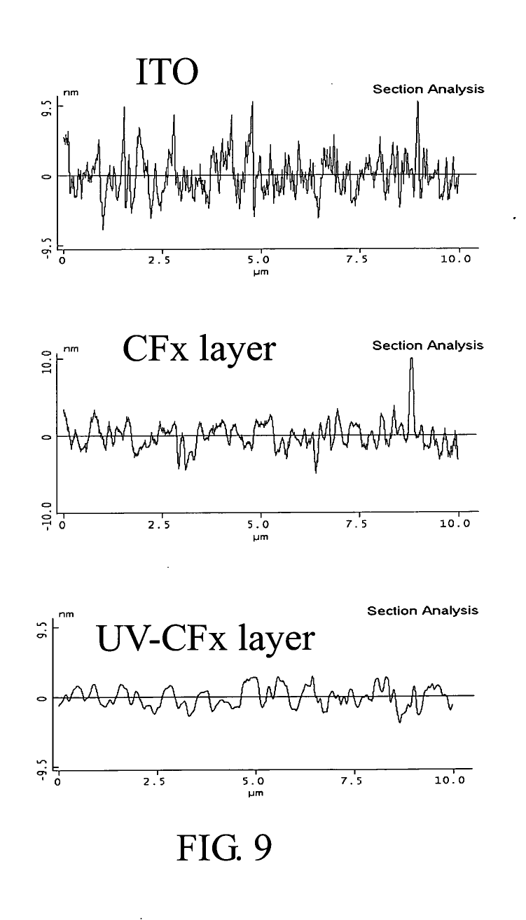

FIGS. 8 and 9 show respectively the 3-dimensional (3-D) AFM images and line scanning profiles of ITO, CFx-coated ITO and UV-CFx-coated ITO respectively. One of the causes of device degradation is the uneven surface of ITO. The sharp spike, with the highest peak-to-peak height is ˜16.96 nm, on ITO is the undesirable feature as shown in FIGS. 8(a) and 9(a). These spikes act as the site to concentrate the electric field and are the source for leakage current. Thus smoothing of ITO surface is an important step to improve device performance.

FIGS. 8(b) and 9(b) present the modification of CFx film on the rough ITO substrate, Root-mean-square-roughness was decreased from 2.12 nm to 1.77 nm. However, some high-frequency features (peak-to-peak height is ˜10 nm) were observed on the CFx layer in FIG. 8(b). These high-frequency features are deleterious to the deposited film for device fabrication. Since short circuit problems frequently arise from the defects or spikes at the organic interface, the stability of the devices are thus badly affected.

FIGS. 8(c) and 9(c) shows that the UV illumination eliminates those high-frequency features. Average peak-to-peak height in the UV-CFx layer is 4.75 nm that is much smaller than that in the CFx layer, and the root-mean-square roughness is reduced to 1.55 nm. Even ignoring the sharp spikes, the average peak-to-peak height of CFx is >7 nm. Thus the insertion of UV-CFx layer could drastically decrease the surface roughness of the anode. The reduced surface roughness of the UV-CFx-coated anode could decrease the distance variation between the electrodes and minimize local hot spots of high electric field, leading to more homogeneous electric field and current density in electroluminescent devices.

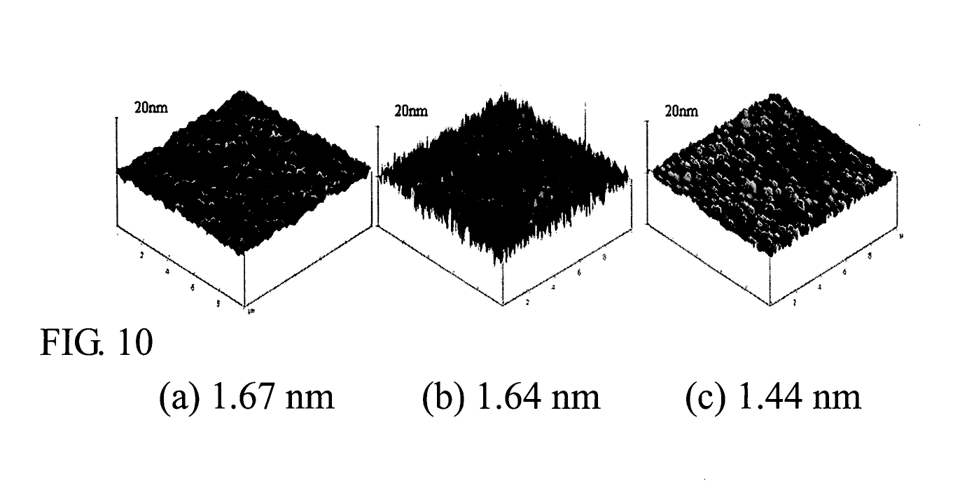

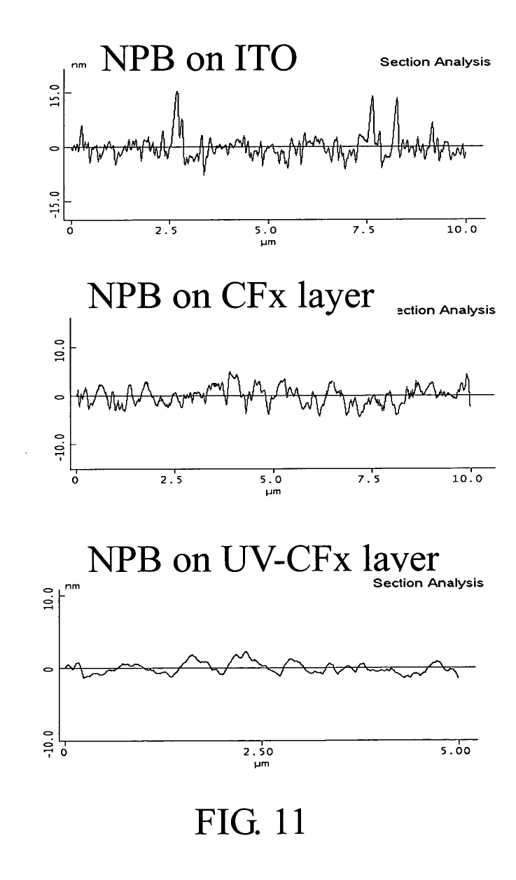

FIGS. 10 and 11 show respectively the 3-D AFM images and line scanning profiles of the 60 nm NPB layer deposited on ITO, CFx-coated ITO and UV-CFx-coated ITO respectively.

UV-CFx on ITO substrate displays the clusters of nodules over the scanned area. The large nodules on NPB surface may result from the several small nodules on the UV-CFx film. FIG. 11(b) and 11(c) shows the peak-to-peak height of CFx layer is halved from 7.14 nm to 3.33 mm after UV illumination. The feature depth and size are improved simultaneously. The improvement in uniformity may be attributed to the increased cross-linking of the films. Smaller surface roughness gives better contact between ITO and NPB. Surface smoothing taking place on UV-CFx can explain the improved device performance.

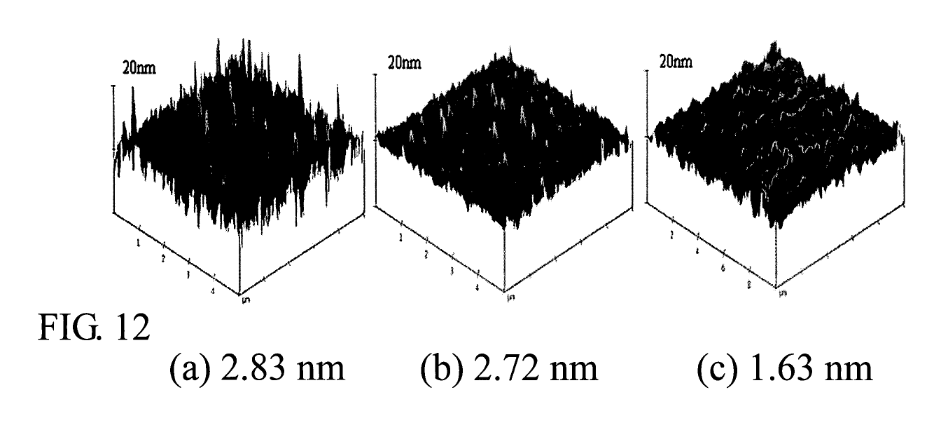

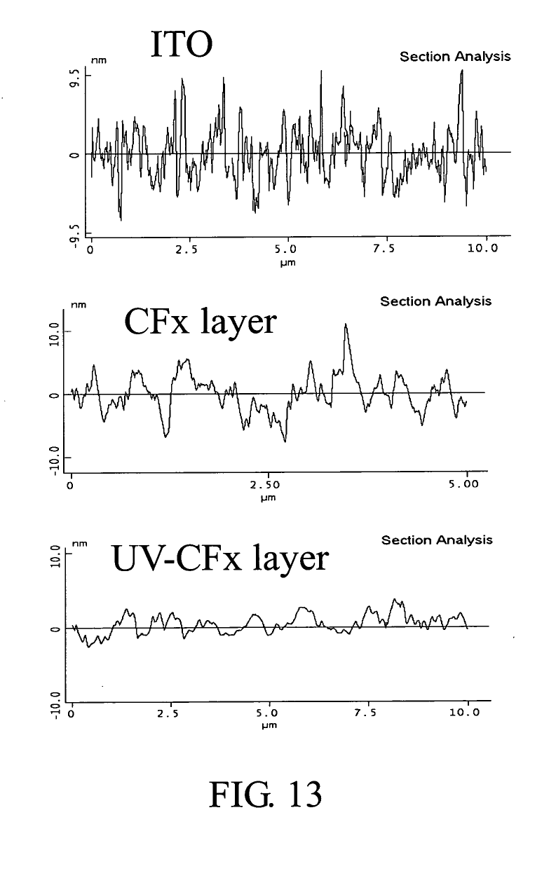

FIGS. 12 and 13 show respectively the 3-D AFM images and line scanning profiles of air-exposed ITO, CFx-coated ITO and UV-CFx-coated ITO respectively. The surface of the UV-CFx-coated ITO remains flat after exposing to air for five days under a relative humidity of 60%. However, the surface of bare ITO and CFx-coated ITO are much rougher than those before air exposure. This indicates that UV-CFx layer is more stable than CFx layer and ITO substrate.

The treatment time for which the fluorocarbon layer is exposed to UV illumination can be considered in terms of the modified resistivity, hole injection property, and surface morphology. Sample CFₓ layers were UV illuminated for periods of 0, 15, 30, 45, and 60 seconds and abbreviated as UVCFx_{—}0, UVCFx_{—}15, UVCFx_{—}30, UVCFx_{—}45 and UVCFx_{—}60 respectively. The results are shown in Table 1 below which shows the resistivity, the hole injection barrier height, the room mean square roughness and the highest peak-to-peak height of the spikes on ITO and CFₓ layers treated with different UV illumination times.

| | Resistivity | Barrier Height | Rrms | peak-to-peak height |
|---|---|---|---|---|
| Layer | (Ω-cm) | (eV) | (nm) | (nm) |
| UVCFx_0 | 10¹⁰->10¹¹ | 0.60 | 1.77 | >7 |
| UVCFx_15 | ˜10⁶ | 0.48 | 1.75 | ˜5.3 |
| UVCFx_30 | ˜10⁵ | 0.46 | 1.55 | ˜4.0 |
| UVCFx_45 | ˜10⁵ | 0.51 | 1.62 | ˜4.6 |
| UVCFx_60 | ˜10⁵ | 0.53 | 1.59 | ˜4.8 |
| ITO | | 0.68 | 2.12 | ˜15.5 |

As shown in Table 1, a remarkable reduction in the resistivity can be provided on the CFₓ layers once they were illuminated by the UV light (from >10¹⁰ to 10⁵ Ω-cm). However, it can be observed that there was no significant further reduction in the resistivity value after 30 s of UV illumination. For the study in hole injecting property, the hole injection barrier heights were compared in the systems of ITO/different UVCFₓ/NPB and ITO/NPB. Table 1 indicates that the barrier height decreases with the increasing illumination time (from 0 s to 30 s), however, additional illumination time led to the increase of the barrier height (from 30 s to 60 s) again. A similar trend was obtained from the morphological study. The Rᵣₘₛ of the CFₓ layer decreased from 1.77 nm to 1.55 nm after illumination of 30 s, while it increased to 1.62 nm after 40 s of illumination. The highest peak-to-peak height of the features on the UVCFx_{—}30 was the lowest value of the samples. Further UV illumination on the UVCFx_{—}30 roughened its morphology. The findings suggested that 30 s of UV illumination should be the optimized treatment time.

The slight increase in barrier height of the UV-CFₓ layers beyond the time of 30 s should be attributed to the ITO involvement. Though the UV illumination might cause the decrease in work function of the ITO surface, and thus increase the hole injection barrier height. The excess UV illumination might remove the oxygen ions from the ITO that led to the decrease in work function.

Though excess UV illumination time would reduce the beneficial parameters (improved conductivity, hole injecting property and smoothness) of the UV-CFₓ layers, it is important to mention that the improvement was still kept compared with the as-deposited CFₓ layers and ITO.

To provide further experimental evidence of the advantageous results of using certain embodiments of the invention, OLEDs with a configuration of substrate/NPB (60 nm)/Alq₃ (60 nm)/Mg:Ag (200 nm) were fabricated. The substrates were respectively ITO glass coated with pristine CFₓ and UV-CFₓ with different UV illumination periods.

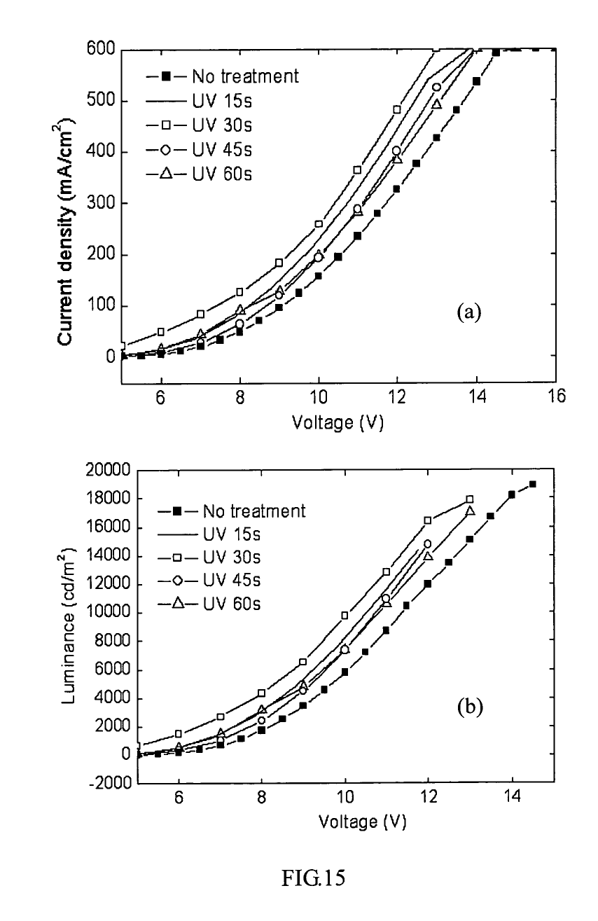

FIG. 15(a) shows the current density as a function of operating voltage for the devices. The use of the UV-illuminated CFₓ buffer significantly improves the device performance. The highest current density at the same driving voltage for OLEDs was obtained using UVCFx_{—}30. It can be observed that there is no significant improvement in the device performance with additional UV illumination beyond 30 s. The luminance of the device with the UVCFx_{—}30 is most significantly enhanced as well (FIG. 15(b). With the operational voltage of 10V, the luminance of the UVCFx_{—}30 device at 10 V is 9727 cd/m² compared to <8300 cd/m² for the device with the UVCFx_t where t is 0, 15, 45 or 60 s.

The characteristic of the UVCFx_{—}30 device is consistent to its properties as shown in Table 1. It suggests that the UVCFx_{—}30 layer has the best properties (the lowest resistivity, the most efficient hole injection property, and the smoothest morphology) than UVCFx_t and provides most beneficial effects in OLED application.

It will thus be seen that ultraviolet radiation may be used to modify the polymers in order to increase their conductivities. Radiation energy is absorbed via ionization, phonon excitation, and atomic displacements, and thus causes bond breaking followed by scissioning and releasing the volatile fragments or by cross-linking through C—C bonding. Clusters of sp²-bonded carbons may be formed, leading to increased conductivity. Ultraviolet radiation is thus a simple method to modify the fluorocarbon films.

It can therefore be seen that the present invention, at least in certain forms, is advantageous because the ultra-violet light can modify the properties of the fluorocarbon layer as follows: increasing the conductivity of the fluorocarbon layer up to five orders of magnitude, smoothing the fluorocarbon layer, the surface having a surface roughness of less than 1.6 nm, improving the hole injection from the fluorocarbon layer coated anode to the organic light-emitting structure, and increasing the stability of the fluorocarbon layer under the atmospheric exposure.

The invention has been described in detail with particular reference to certain embodiments thereof, but it will be understood that variations and modifications can be effected within the spirit and scope of the invention.

What is claimed is:

1. An organic electroluminescent device comprising:
a) a substrate formed of an electrically insulating material;
b) a hole-injecting anode layer mounted on the substrate;
c) a fluorocarbon film treated by illumination with ultra-violet light;
d) an organic light-emitting structure formed over the fluorocarbon film; and
e) an electron-injecting cathode formed by co-evaporating two conductive metals.

2. A device as claimed in claim 1 wherein the insulating substrate is either optically transparent or opaque.

3. A device as claimed in claim 2 wherein the substrate is optically transparent and is formed from glass or plastics materials.

4. A device as claimed in claim 2 wherein the substrate is opaque and is formed from a ceramic or semi-conducting material.

5. A device as claimed in claim 1 wherein the anode is optically transparent with a work function larger than 4 eV.

6. A device as claimed in claim 1 wherein the anode material is chosen from the group consisting of metal oxides, titanium nitride, semi-transparent gold or a conducting polymer.

7. A device as claimed in claim 6 wherein the metal oxides include indium tin oxide, fluorine-doped tin oxide, indium-doped zinc oxide, nickel-tungsten oxide and cadmium-tin oxide.

8. A device as claimed in claim 6 wherein the conducting polymer includes poly(3,4-ethylenedioxythiophene) poly(styrenesulfonate) (PEDOT:PSS) and PSS-doped polyaniline.

9. A device as claimed in claim 1 wherein the fluorocarbon film is either insulating or conducting.

10. A device as claimed in claim 1 wherein the organic light-emitting structure comprises:
i. an organic hole-transporting layer formed on the fluorocarbon film; and
ii. an organic electroluminescent layer formed on the hole-transporting layer.

11. A device as claimed in claim 10 wherein the organic hole-transporting layer is formed of an aromatic tertiary amines.

12. A device as claimed in claim 10 wherein the organic electroluminescent layer is selected from the group consisting of metal chelated oxinoid compounds, 9,10-di-(2-naphthyl) anthracene (DNA), poly(9,9-dioctylfluorene) (PFO) and PFO copolymers.

13. A device as claimed in claim 1 wherein the cathode is formed of a material having a work function no larger than 4 eV.

14. A device as claimed in claim 1 wherein the surface of the fluorocarbon layer has a surface roughness of less than 1.6 nm.

15. A device as claimed in claim 1 wherein the fluorocarbon layer has a resistivity of the order of 10⁵ Ω-cm.

16. A device as claimed in claim 1 wherein the fluorocarbon layer has a resistivity of less than 10⁶ Ω-cm.

17. A method of forming an electroluminescent device comprising:
a) depositing an anode layer on a substrate,
b) depositing a fluorocarbon layer on the anode layer,
c) exposing the fluorocarbon layer to ultra-violet light,
d) forming an organic light-emitting structure over the fluorocarbon layer, and
e) forming an electron-injecting cathode over the organic light-emitting structure.

18. A method as claimed in claim 14, wherein ultra-violet light is supplied by a UV mercury lamp with an intensity of 14 mW/cm².

19. A method as claimed in claim 14 wherein the fluorocarbon layer is exposed to ultra-violet light for at least 30 seconds with a total dosage of at least 420 mJ/cm².
